(19) United States
(12) Patent Application Publication
(10) Pub. No.: US 2016/0148818 A1
(43) Pub. Date: May 26, 2016

(54) TITANIUM OXIDE FILM REMOVAL METHOD AND APPARATUS

(71) Applicant: TOKYO ELECTRON LIMITED, Tokyo (JP)

(72) Inventors: Kazuya DOBASHI, Yamanashi (JP); Akihito HAGIWARA, Yamanashi (JP)

(21) Appl. No.: 14/900,600

(22) PCT Filed: Apr. 9, 2014
(86) PCT No.: PCT/JP2014/060319

§ 371 Date: Dec. 21, 2015

(30) Foreign Application Priority Data
Jun. 21, 2013 (JP) 2013-130936

(51) Int. Cl. H01L 21/311; H01L 21/687; H01L 21/67

(52) U.S. Cl. CPC H01L 21/31111; H01L 21/6708; H01L 21/68764

(57) ABSTRACT

In a titanium oxide film removal method and apparatus, a silicon substrate having the titanium oxide film is supported on a spin chuck. A first mixed aqueous solution including hydrofluoric acid and non-oxidizing acid or a second mixed aqueous solution including hydrofluoric acid and organic acid is supplied to the silicon substrate while rotating the silicon substrate together with the spin chuk. The first or the second aqueous solution comes into contact with the titanium oxide film existing on the silicon substrate to remove the titanium oxide film by a reaction between the first or the second mixed aqueous solution and the titanium oxide film.

### CROSS REFERENCE

This application is a National Stage Application of, and claims priority to, PCT Application No. PCT/JP2014/060319, filed on Apr. 9, 2014, entitled “TITANIUM OXIDE FILM REMOVAL METHOD AND APPARATUS,” which claims priority to Japanese Patent Application No. 2013-130936, filed on Jun. 21, 2013. The foregoing patent applications are herein incorporated by reference by entirety for all purposes.

### FIELD OF THE INVENTION

The present invention relates to a method and apparatus for removing a titanium oxide film existing on a silicon substrate.

### BACKGROUND OF THE INVENTION

In a manufacturing process of a semiconductor device, a TiO₂ film is used as a material of a hard mask used as an etching mask. The TiO₂ film has predominance as a new hard mask material since the TiO₂ film has a good selectivity with respect to other films (Si or SiO₂ film, organic film and the like).

When the TiO₂ film is formed on a silicon substrate, the film forming is performed in a single-substrate type or in a batch-type. However, in a case of a batch-type film forming, the film forming is performed even on a backside of the silicon substrate, so that the TiO₂ film formed on the backside needs to be removed. Moreover, if etching is performed after the TiO₂ film is formed as a hard mask, a film containing titanium and oxygen may be reattached to an end portion of the silicon substrate.

When a subsequent process is performed in a state where the film containing titanium and oxygen reattached to the end portion of the substrate and the TiO₂ film formed on the backside of the substrate (hereinafter, both are called a titanium oxide film) exist, there occurs a problem such as cross contamination between the processes. Accordingly, it is required to remove the titanium oxide film attached. As a method of removing the titanium oxide film without damaging the silicon substrate, there is considered a method that performs a wet cleaning by using, as a chemical solution, hydrofluoric acid (HF). In addition, Patent Document 1 discloses a method of removing the titanium oxide film by using hydrofluoric acid (HF) or buffered hydrofluoric acid (BHF).

### PATENT DOCUMENT

Patent Document 1: Japanese Patent Application Publication No. 2012-500480

However, it has been proved that the TiO₂ film is etched by the hydrofluoric acid at an extremely low etching rate, so that it is not practical.

In an analysis of a ceramic material, a liquid mixture of hydrofluoric acid and nitric acid and a liquid mixture of hydrofluoric acid and sulfuric acid are used in a decomposition method of a TiO₂ specimen. However, it is required to perform a high temperature processing of about 250° C. or a microwave processing together with the method. Accordingly, if considering the application to a semiconductor device, it is difficult to form a hard face. Further, since the liquid mixture of hydrofluoric acid and nitric acid etches silicon and the reactivity is higher than that with TiO₂, it is difficult to apply the liquid mixture to removal of the film on the silicon substrate.

### SUMMARY OF THE INVENTION

In view of the above, the present invention provides a titanium oxide film removal method and apparatus capable of removing a titanium oxide film existing on a silicon substrate at a low temperature with a high speed without damaging the silicon substrate.

In accordance with a first aspect of the present invention, there is provided a method of removing a titanium oxide film, which includes: providing a silicon substrate having the titanium oxide film; making a first mixed aqueous solution including hydrofluoric acid and non-oxidizing acid or a second mixed aqueous solution including hydrofluoric acid and organic acid contact with the titanium oxide film; removing the titanium oxide film from the silicon substrate by a reaction between the first or the second mixed aqueous solution and the titanium oxide film.

In the first aspect, the titanium oxide film may be attached to the silicon substrate or may be formed on an entire surface of a backside of the silicon substrate. The non-oxidizing acid may be selected from a group consisting of hydrochloric acid, sulfuric acid and phosphoric acid. Particularly, the hydrochloric acid is preferable. The organic acid may be selected from a group consisting of acetic acid, formic acid and oxalic acid. Particularly, the acetic acid is preferable.

In the first mixed aqueous solution, a concentration of the hydrofluoric acid may be in a range of 1 to 30 mass % and the concentration of the non-oxidizing acid may be in a range of 2 to 30 mass %. Further, in the second mixed aqueous solution, a concentration of the hydrofluoric acid may be in a range of 1 to 30 mass % and the concentration of the organic acid may be in a range of 40 to 98 mass %. A temperature of the first or the second mixed aqueous solution may be room temperature to 100° C.

The first or the second mixed aqueous solution may be supplied to the silicon substrate while the silicon substrate is rotated.

In accordance with a second aspect of the present invention, there is provided a titanium oxide film removal apparatus for removing a titanium oxide film existing on a silicon substrate, the apparatus including: a support mechanism configured to rotatably support the silicon substrate; a rotation mechanism configured to rotate the support mechanism; a liquid supply unit configured to supply a first mixed aqueous solution including hydrofluoric acid and non-oxidizing acid or a second mixed aqueous solution including hydrofluoric acid and organic acid; and a nozzle configured to eject the first or the second mixed aqueous solution from the liquid supply unit to the silicon substrate supported on the support mechanism, wherein the first or the second mixed aqueous solution ejected from the nozzle contacts with the titanium oxide film existing on the silicon substrate to remove the titanium oxide film.

In accordance with a third aspect of the present invention, there is provided a storage medium storing a program which is operated on a computer to control a titanium oxide film removal apparatus, wherein the program controls, when executed on the computer, the titanium oxide film removal apparatus to perform a method of removing a titanium oxide film, the method including: providing a silicon substrate having the titanium oxide film; making a first mixed aqueous solution including hydrofluoric acid and non-oxidizing acid or a second mixed aqueous solution including hydrofluoric acid and organic acid contact with the titanium oxide film; and removing the titanium oxide film from the silicon substrate by a reaction between the first or the second mixed aqueous solution and the titanium oxide film.

In accordance with the present invention, by making the first mixed aqueous solution including hydrofluoric acid and non-oxidizing acid or the second mixed aqueous solution including hydrofluoric acid and organic acid contact with the titanium oxide film, the titanium oxide film can be removed at a low temperature with a high speed without damaging the silicon substrate.

### BRIEF DESCRIPTION OF THE DRAWINGS

FIG. 1 is a cross sectional view showing a titanium oxide film removal apparatus for performing a method of removing a titanium oxide film in accordance with an embodiment of the present invention.

FIG. 2 is a graph showing an oxidation-reduction potential with respect to the pH of Ti.

FIG. 3 is a view showing reactivities of InP with respect to a HCl solution diluted with pure water and a HCl solution diluted with acetic acid that is an organic acid.

FIG. 4 is a view showing an etching rate of titanium oxide and an etching amount of silicon when the titanium oxide film on a silicon substrate is etched with various aqueous solutions including hydrofluoric acid.

FIG. 5 is a view showing an etching rate of titanium oxide when the concentration of hydrochloric acid and the concentration of acetic acid are changed in a mixed aqueous solution of hydrofluoric acid and hydrochloric acid and a mixed aqueous solution of hydrofluoric acid and acetic acid, respectively.

### DETAILED DESCRIPTION OF THE EMBODIMENTS

The present inventor and others repeatedly carried out various examinations to solve the aformentioned problem. As a result, it has been found that a titanium oxide film existing on a silicon substrate can be removed at a low temperature with a high speed without damaging the silicon substrate by a mixed aqueous solution of hydrofluoric acid and non-oxidizing acid such as hydrochloric acid or the like or by a mixed aqueous solution of hydrofluoric acid and organic acid.

The reason that such mixed aqueous solutions bring the above effect is assumed as follows.

In the mixed aqueous solution of hydrofluoric acid and non-oxidizing acid such as hydrochloric acid or the like, the hydrofluoric acid is a weak acid and the hydrofluoric acid solution has pH of about 2 to 3. However, when the non-oxidizing acid such as hydrochloric acid or the like is added thereto, the pH of the mixed aqueous solution becomes lower. As the pH of the mixed aqueous solution becomes lower, a proportion of Ti ionized in TiO₂ becomes higher. For this reason, it is considered that Ti ions are stably generated by the reaction between the hydrochloric acid and TiO₂ and the etching rate of TiO₂ is increased.

In the mixed aqueous solution of hydrofluoric acid and organic acid, a degree of electrolytic dissociation of the hydrofluoric acid lowers than in an aqueous solution of only hydrofluoric acid. In other words, hydrofluoric acid (HF) concentration in the aqueous solution increases by adding the organic acid. Therefore, it is considered that the increase in the etching rate of TiO₂ by the mixed aqueous solution of hydrofluoric acid and organic acid is because the etching of TiO₂ is performed by undissociated HF.

The present invention is achieved based on such knowledges.

Hereinafter, embodiments of the present invention will be described with respect to the accompanying drawings.

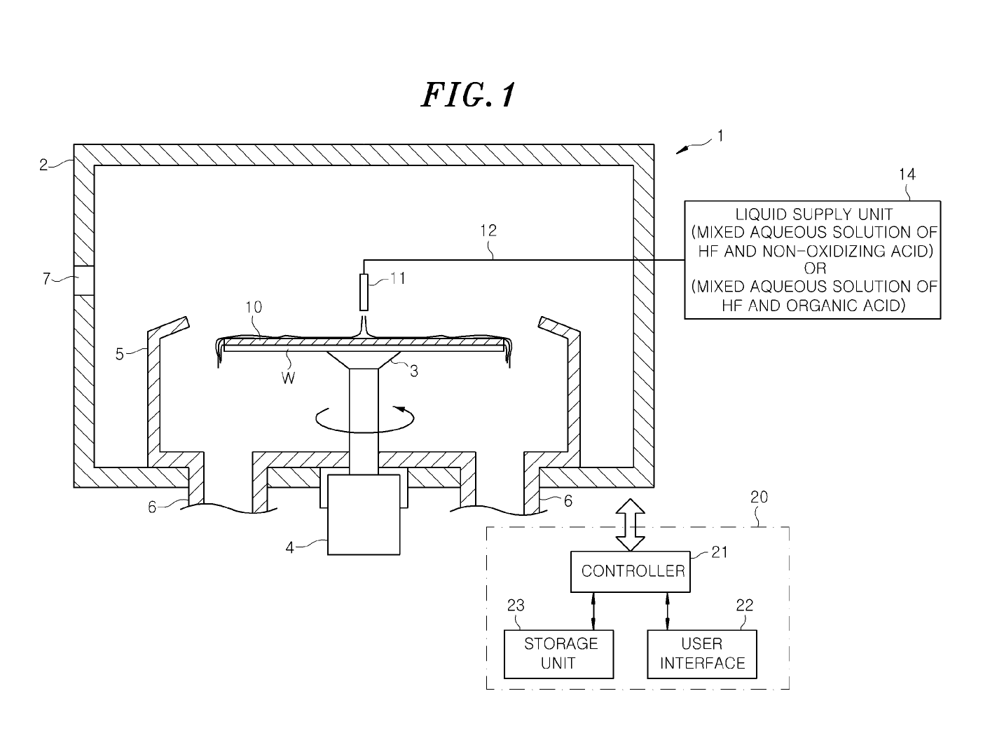

FIG. 1 is a cross-sectional view showing a titanium oxide film removal apparatus for performing a method of removing a titanium oxide film in accordance with an embodiment of the present invention.

The titanium oxide film removal apparatus 1 includes a chamber 2. A substrate W having a TiO₂ film 10 formed on a backside thereof is accommodated in the chamber 2. A silicon substrate (silicon wafer) is used as the substrate W. Alternatively, the substrate W may be one that has a film containing titanium and oxygen which is reattached to an end portion of the substrate W.

The titanium oxide film removal apparatus 1 further includes a spin chuck 3 for horizontally supporting the substrate W by vacuum-suction. The spin chuck 3 can be rotated by a motor 4. A cup 5 is installed in the chamber 2 to cover the substrate W supported on the spin chuck 3. A gas and liquid exhaust line 6 through which a gas and a liquid are exhausted is installed at a bottom portion of the cup 5 to extend under the chamber 2. A loading/unloading port 7 through which the substrate W is loaded and unloaded is provided at a sidewall of the chamber 2. The substrate W is supported on the spin chuck 3 such that the backside on which the TiO₂ film 10 is formed is up.

A nozzle 11 for ejecting a liquid for removing the TiO₂ film 10 formed on the backside of the substrate W is installed above the substrate W supported by the spin chuck 3. The nozzle 11 is movable in horizontal and vertical directions by a driving mechanism (not shown). As shown in FIG. 1, in a case where the TiO₂ film 10 is formed in an entire surface of the backside of the substrate W, the nozzle 11 is arranged above the substrate W at a position corresponding to a center of the substrate W. Further, in a case of removing a film containing titanium and oxygen reattached to an end portion of the substrate W, the nozzle 11 may be arranged at a position depending on the attachment situation of the film.

A liquid supply line 12 is connected to the nozzle 11. A mixed aqueous solution of hydrofluoric acid and a non-oxidizing acid (e.g., hydrochloric acid (HCl)) or a mixed aqueous solution of hydrofluoric acid and organic acid (e.g., acetic acid) is supplied, as a liquid for removing the TiO₂ film 10, through the liquid supply line 12 from a liquid supply unit 14.

The liquid supply unit 14 includes supply sources for respectively supplying hydrofluoric acid, a non-oxidizing acid or an organic acid, and pure water (DIW (deionized water)) and a valve system and a flow rate control system for controlling a mixing ratio thereof. Further, a mixed aqueous solution including both of the non-oxidizing acid and the organic acid may be used.

The titanium oxide film removal apparatus 1 further includes a control unit 20. The control unit 20 includes a controller 21, a user interface 22 and a storage unit 23. The controller 21 includes a microprocessor (computer) which controls the respective components of the titanium oxide film removal apparatus 1, e.g., the motor 4, the driving mechanism of the nozzle 11, the valve system and the flow rate control system of the liquid supply unit 14, and the like. The user interface 22 includes a keyboard through which an operator performs an input operation of a command to manage the titanium oxide film removal apparatus 1, a display on which an operation situation of the titanium oxide film removal apparatus 1 is visually displayed, and the like. The storage unit 23 stores recipes including a control program for controlling control targets of the respective components of the titanium oxide film removal apparatus 1 and a program for allowing the titanium oxide film removal apparatus 1 to perform a predetermined process. The recipes are stored in a storage medium of the storage unit 23. The storage medium may be a fixed one such as a hard disk, or a transportable one such as a CDROM (compact disc read-only memory), a DVD (digital versatile disk), a flash memory and the like. Alternatively, the recipes may be properly transmitted from another device through, e.g., a dedicated line. As occasion demands, a recipe is called from the storage unit 23 by an instruction from the user interface 22 and executed in the controller 21, so that a predetermined process is performed under the control of the controller 21.

Next, description will be made on a method of removing the titanium oxide film existing on the substrate W by using the titanium oxide film removal apparatus 1.

First, the substrate W having the TiO₂ film 10 formed on the backside thereof is loaded into the chamber 2 and supported on the spin chuck 3 in a state where the backside is up. The substrate W has an undesired TiO₂ film formed on the backside of the substrate W in, e.g., a batch type film formation, and the undesired TiO₂ film 10 needs to be removed. Alternatively, the substrate W may have a film containing titanium and oxygen reattached to the end portion of the substrate W by, e.g., the etching of the TiO₂ film, and the reattached film may need to be removed. In this case, depending on the attachment situation of the film, the backside of the substrate W may be placed up or the top surface of the substrate W may be placed up.

Thereafter, the nozzle 11 is placed above the substrate W at a position corresponding to a center of the substrate W. While the substrate W is rotated together with the spin chuck 3 by the motor 4, the mixed aqueous solution of hydrofluoric acid and non-oxidizing acid or the mixed aqueous solution of hydrofluoric acid and organic acid, which serves as a liquid for removing the TiO₂ film 10, is supplied from the liquid supply unit 14 to the upper surface of the substrate W through the liquid supply line 12 and the nozzle 11.

The mixed aqueous solution supplied to the upper surface of the substrate W spreads toward the outer periphery of the substrate W by centrifugal force and reacts with the TiO₂ film 10. The TiO₂ film 10 is removed from the substrate W by the reaction between the mixed aqueous solution and the TiO₂ film 10.

As such, when the mixed aqueous solution of hydrofluoric acid and non-oxidizing acid or the mixed aqueous solution of hydrofluoric acid and organic acid is applied to the TiO₂ film 10, the TiO₂ film 10 solely can be etched and removed at a low temperature with a high speed without damaging a silicon constituting the substrate W. Also in a case of the film containing titanium and oxygen reattached to the end portion of the substrate W, the film can be removed by the mixed aqueous solution of hydrofluoric acid and non-oxidizing acid or the mixed aqueous solution of hydrofluoric acid and organic acid without damaging the silicon, similarly to the TiO₂ film 10.

The reason that the mixed aqueous solutions bring the above effect is assumed as follows.

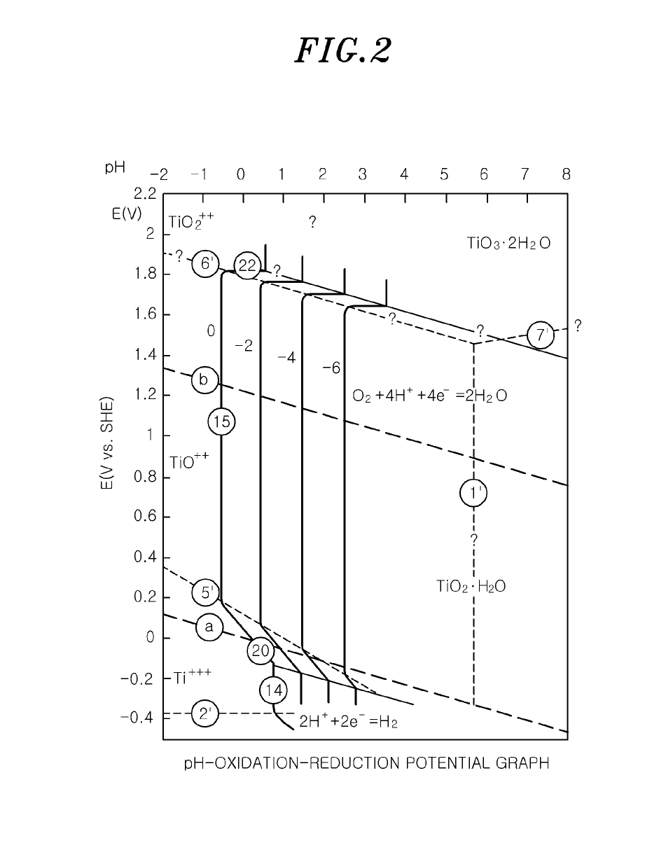

In a case of the mixed aqueous solution of hydrofluoric acid and non-oxidizing acid, the hydrofluoric acid is a weak acid and the hydrofluoric acid solution has pH of about 2 to 3. However, when the non-oxidizing acid such as hydrochloric acid or the like is added thereto, the pH of the mixed aqueous solution becomes lower. FIG. 2 is a graph showing an oxidation-reduction potential with respect to the pH of Ti. Under the existence of H₂O, a region between two inclined broken lines is taken in FIG. 2. As shown in FIG. 2, as the pH becomes lower, a proportion of ionized Ti (TiO⁺⁺) becomes higher. When the pH is smaller than 0, the proportion of the TiO⁺⁺ becomes almost 100%. That is, the ionization is stably performed as the pH is low. Accordingly, it is considered that when using a mixed solution obtained by adding a non-oxidizing acid to hydrofluoric acid to lower the pH, Ti ions are stably generated by the reaction between the hydrochloric acid and TiO₂ and the etching rate of TiO₂ is increased. At this time, it is preferable that the pH is smaller than 0. In a case of the non-oxidizing acid, the mixed aqueous solution of hydrofluoric acid and non-oxidizing acid hardly etches silicon, unlike nitric acid that is an oxidizing acid.

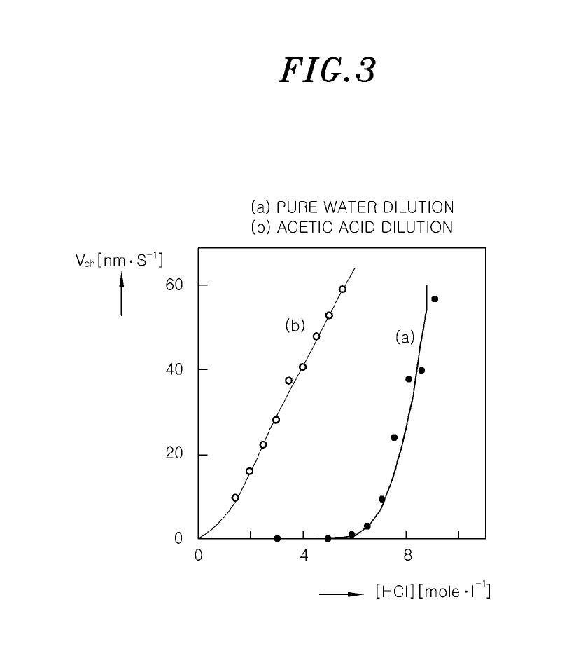

In a case of the mixed aqueous solution of hydrofluoric acid and organic acid, it is considered that the reason is based on a reaction mechanism between InP and HCl. FIG. 3 shows reactivity of InP with respect to a HCl solution diluted with pure water and a HCl solution diluted with acetic acid that is an organic acid (reference: J. Electrochem. Soc., 131, 1984 pp 2643). In FIG. 3, it is seen that in the HCl solution diluted with acetic acid, the etching is performed at a low HCl concentration. Since In-P bonding is cut directly by undissociated HCl, acetic acid dilution brings an effect of lowering a degree of electrolytic dissociation of hydrogen halide. That is, a degree of electrolytic dissociation of HCl is lowered by diluting a HCl solution with acetic acid, and as a result, HCl considerably remains and the etching of InP makes further progress. A similar mechanism is expected in the etching of the TiO₂ film by HF. Accordingly, it is considered that by adding an organic acid, electrolytic dissociation of HF is suppressed to increase HF concentration and the etching of the TiO₂ is progressed.

Since the mixed aqueous solution of hydrofluoric acid and organic acid has a high wettability with respect to the silicon constituting the substrate W, the process efficiency and the process uniformity can be maintained high. This is because, in a case of employing a method in which a chemical solution is supplied while the substrate W is rotated, as the chemical solution has a higher wettability with respect to the substrate, the process efficiency is improved and a more uniform process can be performed. The wettability of the mixed aqueous solution can be controlled by a ratio of the hydrofluoric acid and the organic acid.

As to the hydrofluoric acid in the mixed aqueous solution, the undiluted solution of the hydrofluoric acid is formed of a 50% aqueous solution. Therefore, pure water is inevitably included in the mixed aqueous solution. As to the hydrochloric acid (HCl) that is a typical non-oxidizing acid, the undiluted solution of the hydrochloric acid is formed of a 35% aqueous solution, and thus the amount of pure water is further increased when using the HCl.

The hydrochloric acid is preferable as the non-oxidizing acid, but sulfuric acid (H₂SO₄), phosphoric acid (H₃PO₄) or the like may be used. In a case of using the mixed aqueous solution of hydrofluoric acid and non-oxidizing acid, as described above, the pH of the aqueous solution is preferably controlled to be smaller than 0.

Carboxylic acid, sulphonic acid, or phenols may be used as the organic acid, but the carboxylic acid is preferably used. The carboxylic acid may be expressed as a general formula: R—COOH (where R is hydrogen; alkyl radical or akenyl radical of C₁ to C₂₀ in a straight chain or branched chain; or preferably methyl, ether, propyl, butyl, pentyl, or hexyl). The carboxylic acid may be formic acid (HCOOH), oxalic acid ((COOH)₂), acetic acid (CH₃COOH), propionic acid (CH₃CH₂COOH), butyric acid (CH₃(CH₂)₂COOH), valeric acid (CH₃(CH₂)₃COOH), or the like. Among them, formic acid (HCOOH), oxalic acid ((COOH)₂) and acetic acid (CH₃COOH) are preferable, and acetic acid is more preferable. The concentration of the undiluted solution of the organic acid is close to 100%, unlike the hydrofluoric acid. For example, the concentration of the undiluted solution of the acetic acid is 99%.

Temperatures of the mixed aqueous solution of hydrofluoric acid and non-oxidizing acid and the mixed aqueous solution of hydrofluoric acid and organic acid are each preferably set in a range of room temperature to 100° C. (e.g., 50° C.). The TiO₂ film can be sufficiently removed by each of the mixed aqueous solutions of such a low temperature. It is not required to make the mixed aqueous solutions become a high temperature, unlike the cases of using a liquid mixture of hydrofluoric acid and nitric acid and using a liquid mixture of hydrofluoric acid, sulfuric acid and nitric acid.

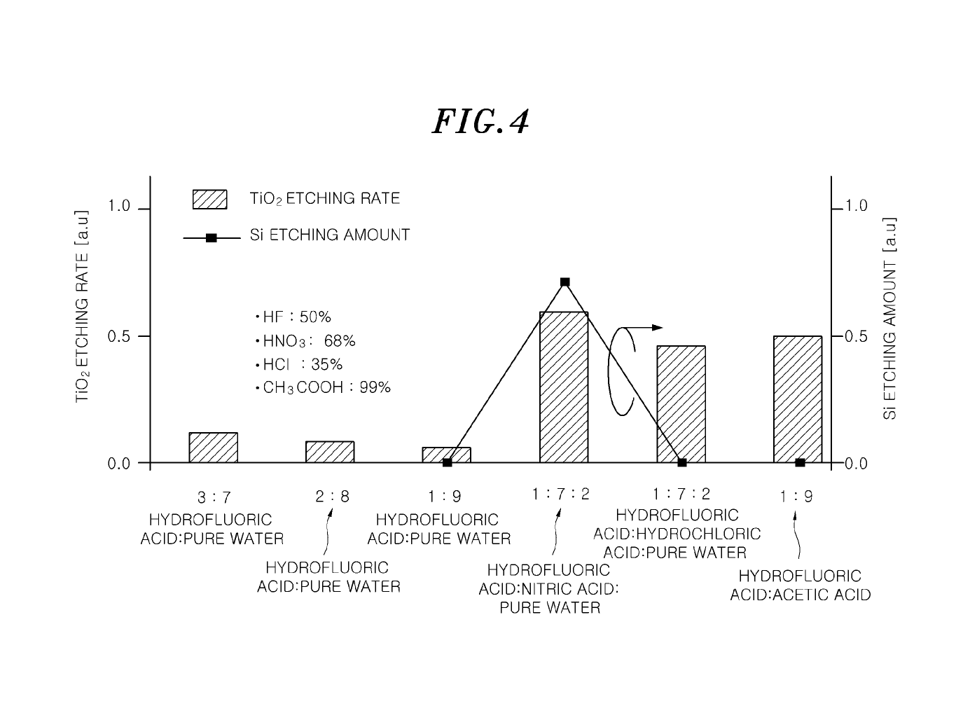

Actually, a test was carried out to confirm that each of the mixed aqueous solutions is effective in removing the TiO₂ film, and the test result is shown as follows. Herein, the TiO₂ film on the silicon substrate was etched by using three types of hydrofluoric acid aqueous solutions (a mass ratio of hydrofluoric acid undiluted solution and pure water was set to 3:7, 2:8 and 1:9), a mixed aqueous solution of hydrofluoric acid and nitric acid (a mass ratio of hydrofluoric acid undiluted solution, nitric acid undiluted solution and pure water was set to 1:7:2), a mixed aqueous solution of hydrofluoric acid and hydrochloric acid (a mass ratio of hydrofluoric acid undiluted solution, hydrochloric acid undiluted solution and pure water was set to 1:7:2), and a mixed aqueous solution of hydrofluoric acid and acetic acid (a mass ratio of hydrofluoric acid undiluted solution and acetic acid undiluted solution was set to 1:9). Temperatures of the aqueous solutions were set to 55° C. An etching rate of the TiO₂ film and an etching amount of silicon is shown in FIG. 4. As shown in FIG. 4, in the hydrofluoric acid aqueous solutions, the etching rate of the TiO₂ film is small regardless of the concentration of the hydrofluoric acid. In contrast, in the mixed aqueous solution of hydrofluoric acid and nitric acid, the mixed aqueous solution of hydrofluoric acid and hydrochloric acid, and the mixed aqueous solution of hydrofluoric acid and acetic acid, the etching rate of the TiO₂ film is extremely increased. However, in the mixed aqueous solution of hydrofluoric acid and nitric acid, silicon is also etched. In this regard, it has been found that in the mixed aqueous solution of hydrofluoric acid and hydrochloric acid and the mixed aqueous solution of hydrofluoric acid and acetic acid, the TiO₂ film can only be etched almost without etching the silicon. Further, with regard to the hydrofluoric acid, the nitric acid, the hydrochloric acid and the acetic acid used herein, the concentrations of the undiluted solutions thereof are 50%, 68%, 35% and 99%, respectively.

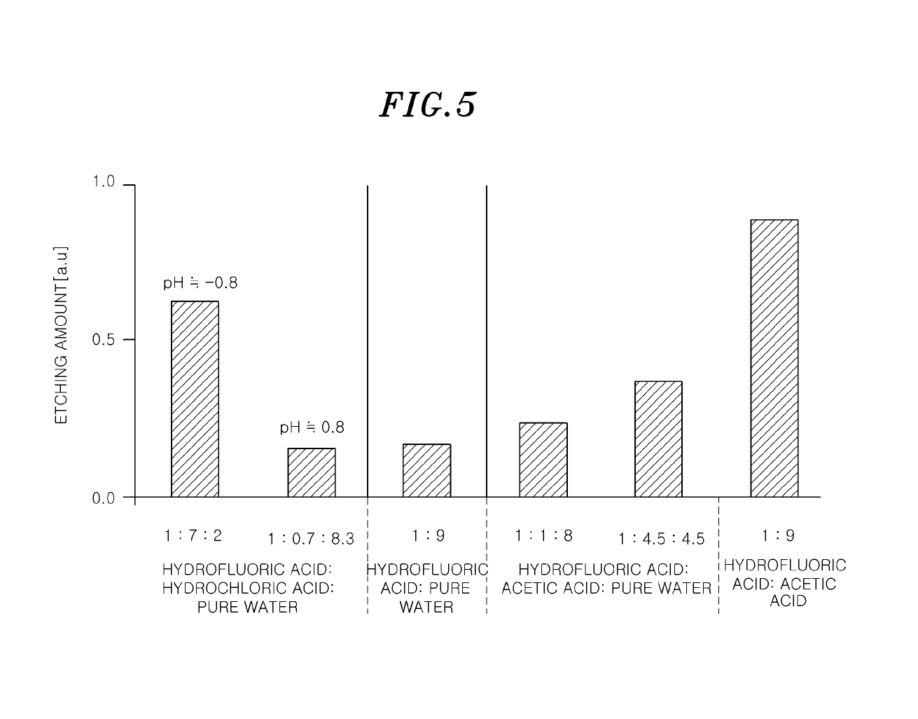

Next, in the mixed aqueous solution of hydrofluoric acid and hydrochloric acid and the mixed aqueous solution of hydrofluoric acid and acetic acid, dependencies of the hydrochloric acid concentration and the acetic acid concentration on an etching rate of the TiO₂ film was examined, and the test result is shown in FIG. 5. Here, the TiO₂ film was etched by using two types of mixed aqueous solutions of hydrofluoric acid and hydrochloric acid (a mass ratio of hydrofluoric acid undiluted solution, hydrochloric acid undiluted solution and pure water was set to 1:7:2 (pH≈−0.8) and 1:0.7:8.3 (pH≈0.8)) and three types of mixed aqueous solutions of hydrofluoric acid and acetic acid (a mass ratio of hydrofluoric acid undiluted solution, acetic acid undiluted solution and pure water was set to 1:1:8 and 1:4.5:4.5, and a mass ratio of hydrofluoric acid undiluted solution and acetic acid undiluted solution was set to 1:9). For comparison, the TiO₂ film was also etched by using a hydrofluoric acid aqueous solution (a mass ratio of hydrofluoric acid undiluted solution and pure water was set to 1:9). Herein, temperatures of the aqueous solutions were set to 55° C.

As shown in FIG. 5, in the mixed aqueous solution of hydrofluoric acid and hydrochloric acid, the etching amount by the mixed aqueous solution in which the mass ratio of hydrofluoric acid undiluted solution, hydrochloric acid undiluted solution and pure water was set to 1:0.7:8.3 (pH≈0.8) is almost equal to the etching amount by the hydrofluoric acid aqueous solution. However, it is expected that in the mixed aqueous solution in which the mass ratio of hydrofluoric acid undiluted solution, hydrochloric acid undiluted solution and pure water was set to 1:1:8 or above, the etching rate can be further improved. In terms of pH, the etching rate is small in pH≈0.8 and the etching amount is remarkably increased in pH≈−0.8 obtained by setting the mass ratio of hydrofluoric acid undiluted solution, hydrochloric acid undiluted solution and pure water to 1:7:2. From this, it has been found that adding the hydrochloric acid is preferable to make the pH smaller than 0. Accordingly, in a case of adding the hydrochloric acid, it may be defined by pH instead of an added amount of the hydrochloric acid.

In the mixed aqueous solution of hydrofluoric acid and acetic acid, the etching rate of the mixed aqueous solution in which the mass ratio of hydrofluoric acid undiluted solution, acetic acid undiluted solution and pure water was set to 1:1:8 (acetic acid: 10 mass %) becomes slightly higher than the etching rate of the hydrofluoric acid aqueous solution. However, the etching amount is increased by using the mixed aqueous solution in which the mass ratio of hydrofluoric acid undiluted solution, acetic acid undiluted solution and pure water was set to 1:4.5:4.5 (acetic acid: 45 mass %) or above. From this, it is preferable that the acetic acid is 40 mass % or above. Similar result was obtained in a case of using formic acid instead of the acetic acid.

From the above result, in the case of using the mixed aqueous solution of hydrofluoric acid and hydrochloric acid (non-oxidizing acid), it is preferable that the concentration of the hydrofluoric acid (HF) is set to 1 to 30 mass % and the concentration of the hydrochloric acid (HCl) is set to 2 to 30 mass %. This holds true for other non-oxidizing acids. The remainder is pure water. However, since, as described above, the undiluted solution of the hydrofluoric acid is 50% aqueous solution and the undiluted solution of the hydrochloric acid is 35% aqueous solution, the ratio needs to be determined in consideration of the amount of pure water in the undiluted solution. For example, when the concentration of the hydrochloric acid is 30 mass %, the amount of pure water becomes 55.7 mass % and the remainder, i.e., 14.3 mass % is set by the hydrofluoric acid undiluted solution and pure water according to the need.

In the case of using the mixed aqueous solution of hydrofluoric acid and organic acid (acetic acid), it is preferable that the concentration of the hydrofluoric acid (HF) is set to 1 to 30 mass % and the concentration of the organic acid is set to 40 to 98 mass %. The remainder is pure water. However, since, as described above, the undiluted solution of the hydrofluoric acid is 50% aqueous solution, when the concentration of the hydrofluoric acid is, e.g., the maximum, i.e., 30 mass %, the concentration of the pure water becomes 30 mass % and the concentration of the organic acid becomes almost 40 mass %. If the undiluted solutions of the hydrofluoric acid and the organic acid are only used and pure water is not additionally added, the concentration of the pure water becomes in a range of almost 1 to 30 mass %.

As above, in accordance with the present embodiment, by supplying the mixed aqueous solution of hydrofluoric acid and non-oxidizing acid or the mixed aqueous solution of hydrofluoric acid and organic acid to the silicon substrate W having the TiO₂ film 10 formed on the backside thereof, the TiO₂ film 10 is removed from the silicon substrate W.

By doing so, the TiO₂ film 10 formed on the backside of the silicon substrate W can be removed at a low temperature with a high speed withough damaging the silicon substrate W. Similarly, also in a case of a film containing titanium and oxygen reattached to an end portion of the substrate W, the film can be removed at a low temperature with a high speed without damaging the silicon substrate W by supplying the mixed aqueous solution of hydrofluoric acid and non-oxidizing acid or the mixed aqueous solution of hydrofluoric acid and organic acid.

While the present invention has been described with respect to the embodiment, it can be variously modified without being limited to the above embodiment. For example, in the above embodiment, there has been shown a case where the substrate is supported on the spin chuck and a liquid mixture is supplied from the nozzle arranged above the substrate. However, the configuration is not limited thereto but the nozzle may be provided at the side of the backside of the substrate or at the outer side of the substrate. That is, an appropriate configuration of the apparatus may be employed depending on an attachment situation of the titanium oxide film.

### DESCRIPTION OF REFERENCE NUMERALS

1: titanium oxide film removal apparatus
2: chamber
3: spin chuck
4: motor
5: cup
6: gas and liquid exhaust line
7: loading/unloading port
11: nozzle
12: liquid supply line
14: liquid supply unit
20: control unit
21: controller
22: user interface
23: storage unit
W: substrate (silicon substrate)

What is claimed is:

1. A method of removing a titanium oxide film, comprising:
providing a silicon substrate having the titanium oxide film;
making a first mixed aqueous solution including hydrofluoric acid and non-oxidizing acid or a second mixed aqueous solution including hydrofluoric acid and organic acid contact with the titanium oxide film, wherein the non-oxidizing acid is for decreasing pH of the hydrofluoric acid to increase a proportion of ionized titanium, pH of the first mixed aqueous solution becoming smaller than 0 by addition of the non-oxidizing acid, and the organic acid is for suppressing electrolytic dissociation of the hydrofluoric acid to increase a concentration of the hydrofluoric acid;
removing the titanium oxide film from the silicon substrate by a reaction between the first or the second mixed aqueous solution and the titanium oxide film.

2. The method of claim 1, wherein the titanium oxide film is attached to the silicon substrate or is formed on an entire surface of a backside of the silicon substrate.

3. The method of claim 1, wherein the non-oxidizing acid is selected from a group consisting of hydrochloric acid, sulfuric acid and phosphoric acid.

4. The method of claim 1, wherein the organic acid is selected from a group consisting of acetic acid, formic acid and oxalic acid.

5. The method of claim 1, wherein in the first mixed aqueous solution, a concentration of the hydrofluoric acid is in a range of 1 to 30 mass % and the concentration of the non-oxidizing acid is in a range of 2 to 30 mass %.

6. The method of claim 1, wherein in the second mixed aqueous solution, a concentration of the hydrofluoric acid is in a range of 1 to 30 mass % and the concentration of the organic acid is in a range of 40 to 98 mass %.

7. The method of claim 1, wherein a temperature of the first or the second mixed aqueous solution is room temperature to 100° C.

8. The method of claim 1, wherein the first or the second mixed aqueous solution is supplied to the silicon substrate while the silicon substrate is rotated.

9. A titanium oxide film removal apparatus for removing a titanium oxide film existing on a silicon substrate, the apparatus comprising:
a support mechanism configured to rotatably support the silicon substrate;
a rotation mechanism configured to rotate the support mechanism;
a liquid supply unit configured to supply a first mixed aqueous solution including hydrofluoric acid and non-oxidizing acid or a second mixed aqueous solution including hydrofluoric acid and organic acid, wherein the non-oxidizing acid is for decreasing pH of the hydrofluoric acid to increase a proportion of ionized titanium, pH of the first mixed aqueous solution becoming smaller than 0 by addition of the non-oxidizing acid, and the organic acid is for suppressing electrolytic dissociation of the hydrofluoric acid to increase a concentration of the hydrofluoric acid; and
a nozzle configured to eject the first or the second mixed aqueous solution from the liquid supply unit to the silicon substrate supported on the support mechanism,
wherein the first or the second mixed aqueous solution ejected from the nozzle contacts with the titanium oxide film existing on the silicon substrate to remove the titanium oxide film.

10. The titanium oxide film removal apparatus of claim 9, wherein the non-oxidizing acid is selected from a group consisting of hydrochloric acid, sulfuric acid and phosphoric acid.

11. The titanium oxide film removal apparatus of claim 9, wherein the organic acid is selected from a group consisting of acetic acid, formic acid and oxalic acid.

12. The titanium oxide film removal apparatus of claim 9, wherein the liquid supply unit supplies the first mixed aqueous solution in which a concentration of the hydrofluoric acid is set in a range of 1 to 30 mass % and the concentration of the non-oxidizing acid is set in a range of 2 to 30 mass %.

13. The titanium oxide film removal apparatus of claim 9, wherein the liquid supply unit supplies the second mixed aqueous solution in which a concentration of the hydrofluoric acid is set in a range of 1 to 30 mass % and the concentration of the organic acid is set in a range of 40 to 98 mass %.

14. The titanium oxide film removal apparatus of claim 9, wherein the liquid supply unit supplies the first or the second mixed aqueous solution of room temperature to 100° C.

15. A storage medium storing a program which is operated on a computer to control a titanium oxide film removal apparatus,
wherein the program controls, when executed on the computer, the titanium oxide film removal apparatus to perform a method of removing a titanium oxide film, the method including: providing a silicon substrate having the titanium oxide film; making a first mixed aqueous solution including hydrofluoric acid and non-oxidizing acid or a second mixed aqueous solution including hydrofluoric acid and organic acid contact with the titanium oxide film, wherein the non-oxidizing acid is for decreasing pH of the hydrofluoric acid to increase a proportion of ionized titanium, pH of the first mixed aqueous solution becoming smaller than 0 by addition of the non-oxidizing acid, and the organic acid is for suppressing electrolytic dissociation of the hydrofluoric acid to increase a concentration of the hydrofluoric acid; and removing the titanium oxide film from the silicon substrate by a reaction between the first or the second mixed aqueous solution and the titanium oxide film.
